(19) United States
(12) Patent Application Publication
(10) Pub. No.: US 2008/0121984 A1
(43) Pub. Date: May 29, 2008

(54) Flash memory structure and method for fabricating the same

(75) Inventors: Jason Chen, Chupei City (TW); Chien Kang Kao, Hsinchu City (TW)

Correspondence Address: OLIFF & BERRIDGE, PLC, P.O. BOX 320850, ALEXANDRIA, VA, 22320-4850, US

(73) Assignee: PROMOS TECHNOLOGIES INC., Hsinchu (TW)

(21) Appl. No.: 12/010,827

(22) Filed: Jan. 30, 2008

Related U.S. Application Data
(63) Continuation-in-part of application No. 11/288,194, filed on Nov. 29, 2005.

(51) Int. Cl. H01L 29/788

(52) U.S. Cl. 257/325; 257/324; 257/E29.3

(57) ABSTRACT

A flash memory structure comprises a silicon substrate having at least one concave structure, two doped regions positioned in the semiconductor substrate and at two sides of the concave structure, at least one carrier-trapping region positioned in the concave structure, and a conductive layer positioned above the concave structure. The concave structure comprises two grooves having a U-shaped or V-shaped profile. The grooves have an inclined plane with (111) orientation and a bottom plane with (100) orientation of the silicon substrate. The carrier-trapping region comprises a dielectric stack positioned in the concave structure, wherein the dielectric stack comprises a first oxide layer positioned on the surface of the silicon substrate, a nitride block positioned on the surface of the first oxide layer and in the concave structure, and a second oxide layer covering the first oxide layer and the nitride block.

This application is a Continuation-In-Part (CIP) of U.S. patent application Ser. No. 11/288,194 filed on Nov. 29, 2005, and the disclosure of which is incorporated by reference.

### BACKGROUND OF THE INVENTION

(A) Field of the Invention

The present invention relates to a flash memory structure and method for fabricating the same, and more particularly, to a flash memory structure having separated carrier-trapping regions and the method for fabricating the same.

(B) Description of the Related Art

Flash memory has been widely applied to the data storage of digital products such as laptop computers, personal digital assistants, cell phones, digital cameras, digital recorders, and MP3 players. A typical flash memory comprises a silicon-oxide-nitride-oxide-silicon (SONOS) structure, which is widely used in flash memory since it possesses the advantages of a thinner memory cell and a simple fabrication process.

FIG. 1 illustrates a flash memory cell 10 with a SONOS structure according to the prior art. The flash memory cell 10 comprises a silicon substrate 12, two doped regions 14 and 16, a tunnel oxide layer 22, a silicon nitride layer 24, a silicon oxide layer 26, and a polysilicon layer 28. Particularly, the SONOS structure 20 consists of the silicon substrate 12, the tunnel oxide layer 22, the silicon nitride layer 24, the silicon oxide layer 26, and the polysilicon layer 28. While carrier-trapping regions in the silicon nitride layer 24 can capture electrons or holes penetrating the tunnel oxide 22, the silicon oxide layer 26 serves to prevent electrons and holes from escaping the silicon nitride layer 24 to enter into the polysilicon layer 28 during writing or erasing operations of the flash memory.

When the polysilicon layer 28, serving as the gate electrode, is connected to a positive potential, electrons in the silicon substrate 12 will inject into the silicon nitride layer 24. Inversely, a portion of electrons in the silicon nitride layer 24 will be repulsed to inject into the silicon substrate 12 to form holes in the silicon nitride layer 24 when the polysilicon layer 28 is connected to a negative potential. Electrons and holes trapped in the silicon nitride layer 24 change the threshold voltage (Vₜₕ) of the flash memory cell 10, and different threshold voltages represent that the flash memory stores different data bits, i.e., “1” and “0.”

### SUMMARY OF THE INVENTION

The objective of the present invention is to provide a flash memory structure having separated carrier-trapping regions and the method for fabricating the same, which possesses a higher storage density and better step coverage property.

In order to achieve the above-mentioned objective and avoid the problems of the prior art, one embodiment of the present invention discloses a flash memory structure comprising a semiconductor substrate having at least one concave structure, two doped regions positioned in the semiconductor substrate and at two sides of the concave structure, at least one carrier-trapping region positioned in the concave structure, and a conductive layer positioned above the concave structure. The concave structure may comprise two grooves having a U-shaped or V-shaped profile, which are separated by a protrusion. The semiconductor substrate can be a silicon substrate, and the groove has an inclined plane with a (111) orientation and a bottom plane with a (100) orientation. The carrier-trapping regions comprise a dielectric stack positioned in the concave structure, wherein the dielectric stack comprises a first oxide layer positioned on the surface of the silicon substrate, a nitride block positioned on the surface of the first oxide layer and in the concave structure, and a second oxide layer covering the first oxide layer and the nitride block.

The method for fabricating a flash memory structure comprises steps of forming: two doped regions in a semiconductor substrate, one concave structure on the surface of the semiconductor substrate, at least one carrier-trapping region in the concave structure, and a conductive layer above the concave structure. Preferably, the semiconductor substrate is a silicon substrate. The formation of the concave structure may comprise steps of forming: a silicon epitaxy layer on the surface of the silicon substrate, a mask layer on the surface of the silicon epitaxy layer, and at least one opening in the mask layer, followed by an etching process to remove a portion of the silicon epitaxy layer below the opening to form the concave structure including at least one groove, and removal of the mask layer. The mask layer may be an oxide layer, and the etching process may use an etchant including potassium hydroxide (KOH).

The formation of at least one carrier-trapping region may comprise steps of forming a first oxide layer on the surface of the silicon epitaxy layer, depositing a nitride layer on the first oxide layer, forming a photoresist layer on the nitride layer, performing a photolithographic process to remove a portion of the photoresist layer above a predetermined depth to form a photoresist mask, performing an etching process to remove a portion of the nitride layer not covered by the photoresist mask to form the nitride block on the surface of the first oxide layer in the groove, removing the photoresist mask, and forming a second oxide layer on the surface of the nitride block and the surface of the first oxide layer.

Compared to the prior art, the present flash memory structure possesses a higher storage density and the method for fabricating the flash memory possesses a better step coverage property. The present flash memory structure has two carrier-trapping regions in one memory cell, which can store two bits of data, i.e., the memory cell is a twin bit cell. Since a single memory cell can store two bits of data, the present flash memory structure possesses a higher storage density. Further, the width of the concave structure is larger at the top region than at the bottom region, and the dielectric stack and the conductive layer can be prepared by deposition processes with a better step coverage property, which will not form a void in the dielectric stack or in the conductive layer.

### BRIEF DESCRIPTION OF THE DRAWINGS

The objectives and advantages of the present invention will become apparent upon reading the following description and upon reference to the accompanying drawings in which:

FIG. 1 illustrates a flash memory cell with a SONOS structure according to the prior art;

FIG. 2 to FIG. 9 illustrate a method for fabricating a flash memory structure according to one embodiment of the present invention;

FIG. 10 to FIG. 15 illustrate a method for fabricating a flash memory structure according to another embodiment of the present invention;

FIG. 16 illustrates a flash memory structure having a dielectric stack 190 according to another embodiment of the present invention; and

FIG. 17 illustrates a flash memory structure including a dielectric stack having a plurality of trapping sites disposed therein according to another embodiment of the present invention.

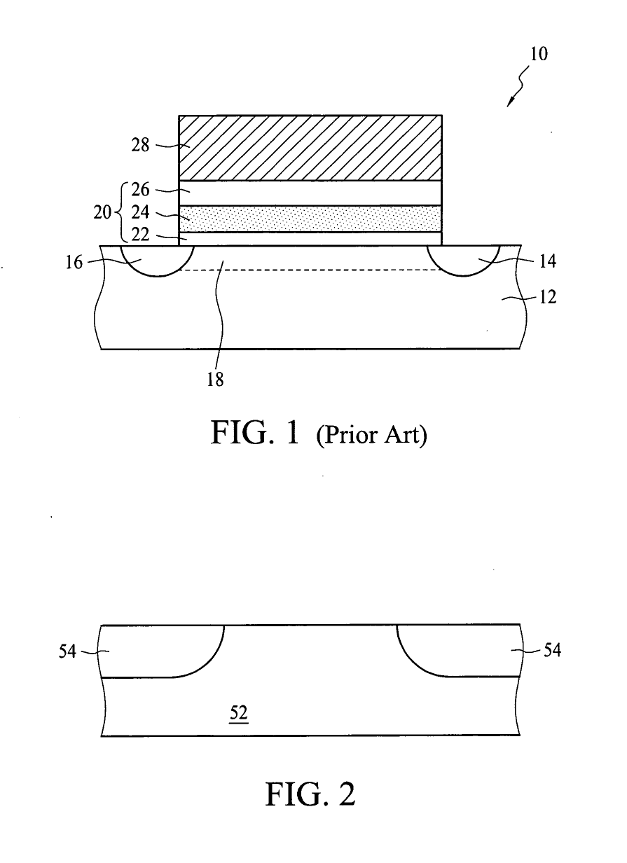

### DETAILED DESCRIPTION OF THE INVENTION

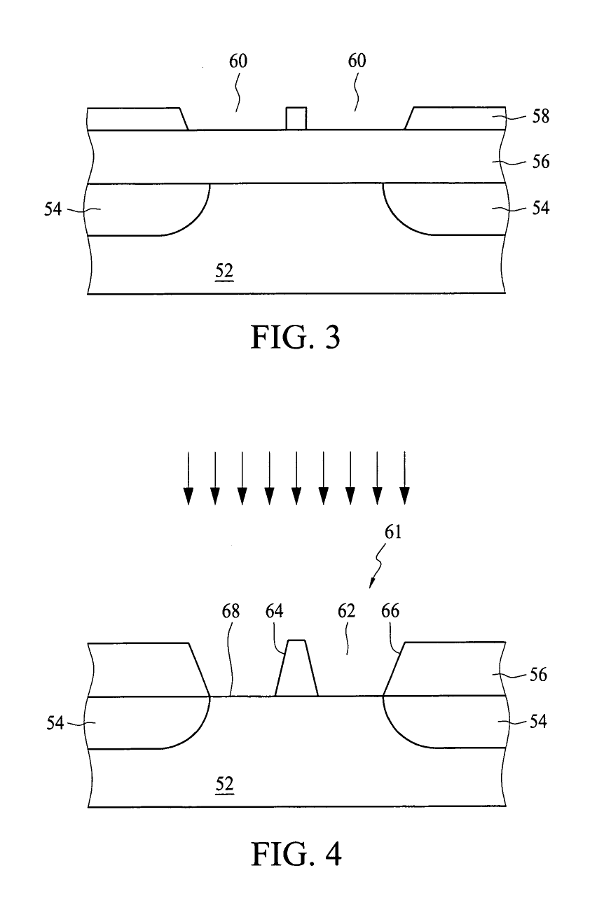

FIG. 2 to FIG. 9 illustrate a method for fabricating a flash memory structure 50 according to one embodiment of the present invention. Two doped regions 54 are formed in a silicon substrate 52 by an n⁺ ion implanting process, wherein these two doped regions 54 serve as a source electrode and a drain electrode, respectively, of a transistor. Subsequently, a silicon epitaxy layer 56 is formed on the surface of the silicon substrate 52, a mask layer 58 is formed on the surface of the silicon epitaxy layer 56, and a photolithographic process is then performed to form two openings 60 in the mask layer 58, as shown in FIG. 3. Preferably, the mask layer 58 is a silicon oxide layer, and the silicon substrate 52 has a horizontally positioned crystal plane with (100) orientation.

Referring to FIG. 4, an etching process is performed using the mask layer 58 as an etching mask to remove a portion of the silicon epitaxy layer 56 below these two openings 60 to form a concave structure 61 having two grooves 62, and the mask layer 58 is then completely removed. Another ion implanting process is then performed to implant ions into the silicon substrate 52 to modify the threshold voltage (Vₜₕ) of the transistor. These two grooves 62 are separated by a protrusion 64, which has a bottom width preferably larger than 100 angstroms to substantially separate these two grooves 62. Particularly, the etching process uses an etchant including potassium hydroxide, and the groove 62 has an inclined plane 62 with (111) orientation, and a bottom plane 68 with (100) orientation of the silicon epitaxy layer 56.

The etchant removes the silicon epitaxy layer 56 at a rate of 0.6 micrometer/minute along the crystal plane (100) orientation and at a rate of 0.006 micrometer/minute along the crystal plane (111) orientation at 80° C., i.e., the etching process is orientation-independent, which can form these two grooves 62 with the inclined plane 66 with (111) orientation of the silicon epitaxy layer 56 automatically. On the one hand the groove 62 will have a V-shaped profile if the width of the opening 60 is smaller and the etching process is performed for a shorter duration; on the other hand the groove 62 will have a U-shaped profile if the if the width of the opening 60 is larger and the etching process is performed for a longer duration.

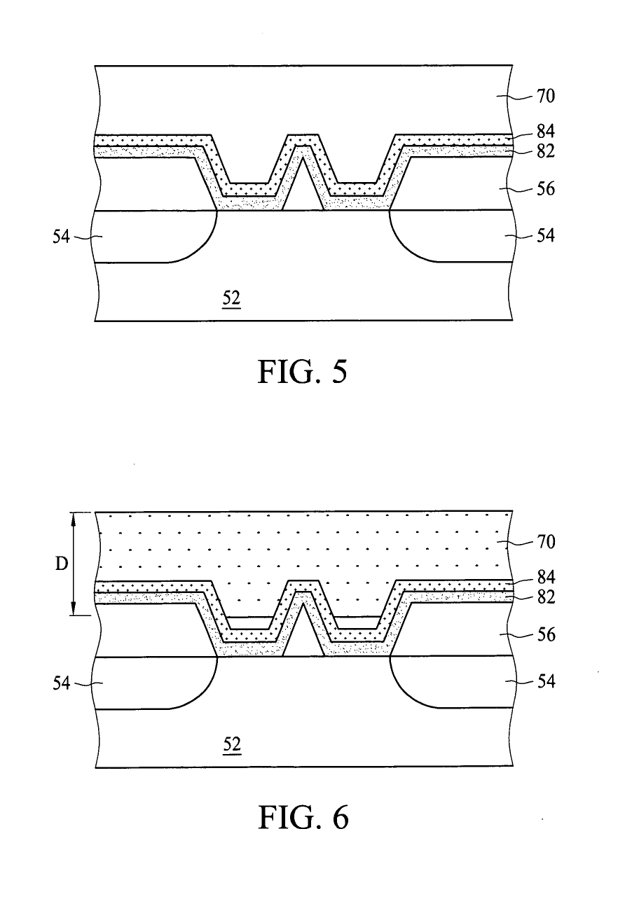

Referring to FIG. 5, deposition processes are performed to form a first oxide layer 82 on the surface of the silicon epitaxy layer 56 and a nitride layer 84 on the first oxide layer 82, and a photoresist layer 70 is then formed on the nitride layer 84. A portion of the photoresist layer 70 above a predetermined depth “D” is exposed by controlling the illumination intensity of the exposure process. In other words, a portion of the photoresist layer 70 at the bottom of the groove 62 is not exposed and maintains its original molecular structure, while the other portion of the photoresist layer 70 not at the bottom of the groove 62 receives sufficient illumination intensity to alter its molecular structure, as shown in FIG. 6.

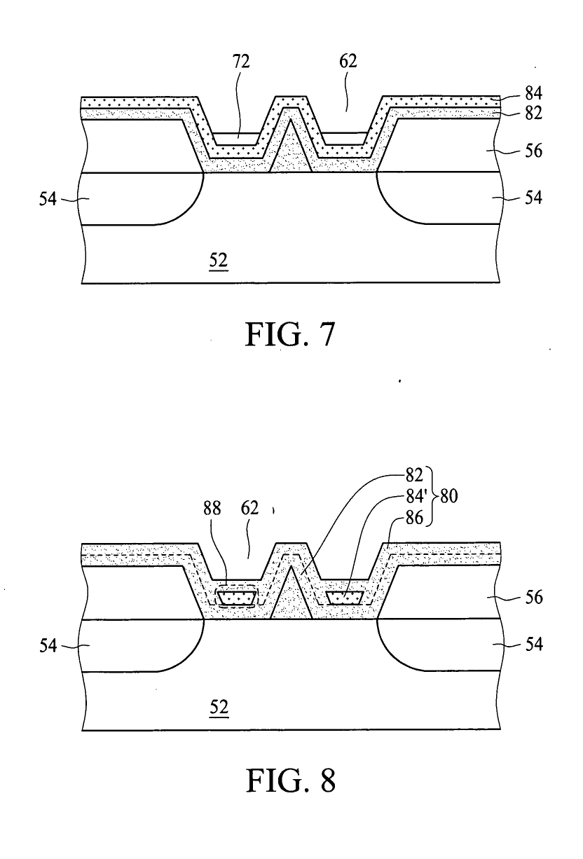

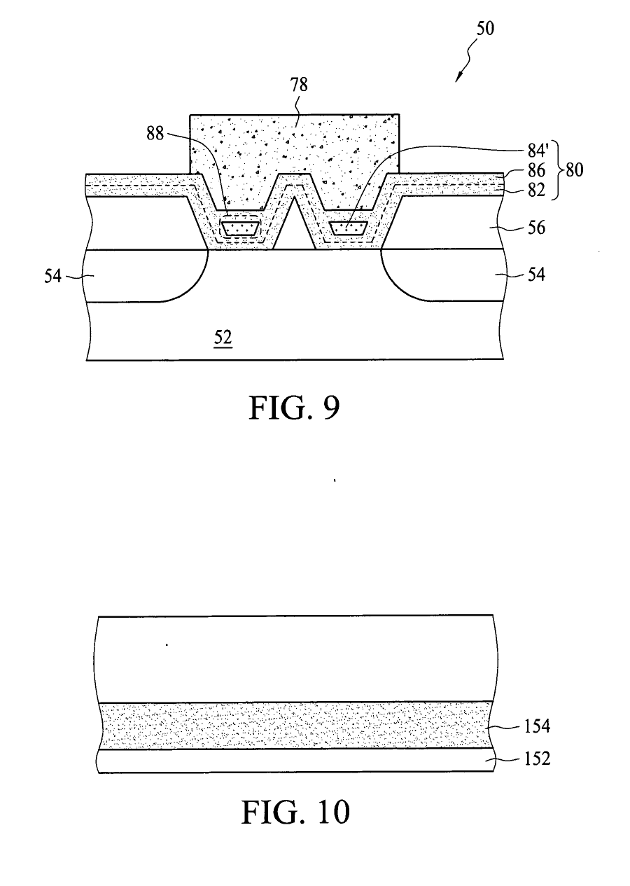

Referring to FIG. 7, a developing process is performed to remove a portion of the photoresist layer 70 above a predetermined depth “D” to form a photoresist mask 72. Subsequently, the photoresist mask 72 is used as an etching mask to perform an etching process that removes a portion of the nitride layer 84 not covered by the photoresist mask 72, forming two nitride blocks 84′ on the surface of the first oxide layer 82 and in the groove 62. Subsequently, a deposition process is performed to form a second oxide layer 86 on the surface of the nitride block 84′ and the surface of the first oxide layer 82, as shown in FIG. 8. Particularly, a dielectric stack 80 consists of the first oxide layer 82, the nitride block 84′, and the second oxide layer 86, wherein the dielectric stack 80 in the groove 62 forms two carrier-trapping regions 88. A conductive layer 78 made of polysilicon, which serves as a gate electrode of the transistor, is formed on the surface of the dielectric stack 80 above the groove 62 to complete the flash memory structure 50, as shown in FIG. 9.

Compared to the prior art, the present flash memory structure possesses a higher storage density and the method for fabricating the flash memory possesses a better step coverage property. The present flash memory structure has two carrier-trapping regions in one memory cell, which can store two bits of data, i.e., the memory cell is a twin bit cell. Since a single memory cell can store two bits of data, the present flash memory structure possesses a higher storage density. Further, the width of the concave structure is larger at the top region than at the bottom region, and the dielectric stack and the conductive layer can be prepared by deposition process with a better step coverage property, which will not form a void in the dielectric stack or in the conductive layer.

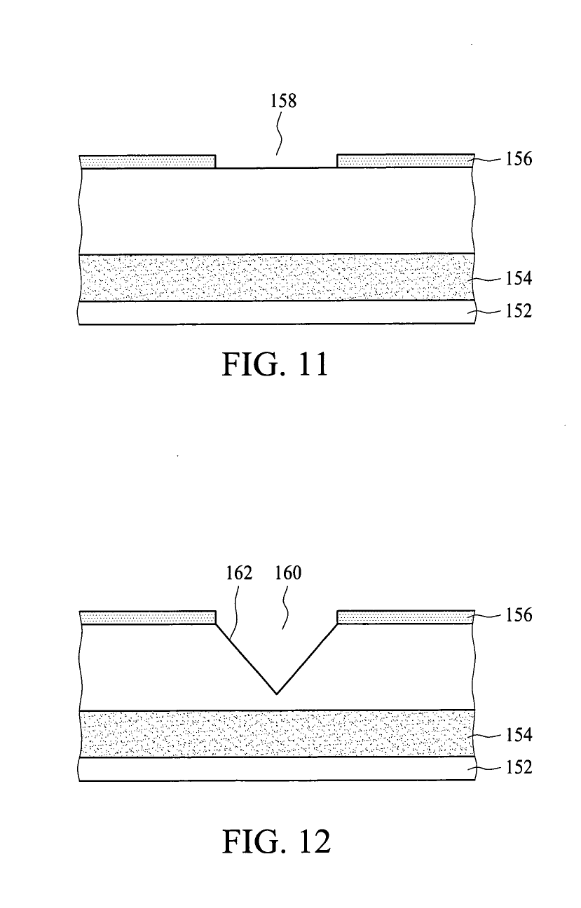

FIG. 10 to FIG. 15 illustrate a method for fabricating a flash memory structure 150 according to another embodiment of the present invention. A doped region 154 is formed in a silicon substrate 152 by an n⁺ ion implanting process, and the implanting energy is preferably between 20 and 30 keV to implant dopants into a depth between 1600 and 2000 angstroms. A mask layer 156 is formed on the surface of the silicon substrate 152, and a photolithographic process is then performed to form an opening 158 in the mask layer 156, as shown in FIG. 11. Preferably, the mask layer 156 is a silicon oxide layer, and the silicon substrate 152 is (100)-oriented.

Referring to FIG. 12, an etching process is performed to remove a portion of the silicon substrate 152 below the opening 158 to form a V-shaped groove 160, and the mask layer 156 is then completely removed. Particularly, the etching process uses an etchant including potassium hydroxide, and the V-shaped groove 160 has inclined surface planes 162 with (111) orientation. The etchant removes the silicon substrate 152 at a rate of 0.6 micrometer/minute along the planes with (100) orientation and at a rate of 0.006 micrometer/minute along the planes with (111) orientation at 80° C., i.e., the etching process is orientation-independent, which can form the V-shaped groove 160 with the inclined surface planes 162 with (111) orientation automatically.

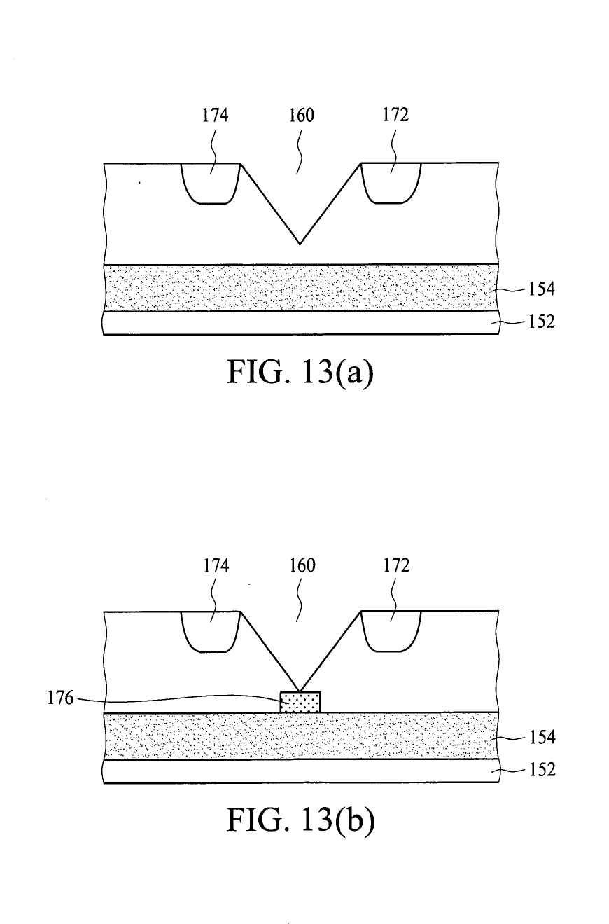

Referring to FIG. 13(a), another n⁺ ion implanting process is performed to form two doped regions 172 and 174 in the silicon substrate 152 and at two sides of the V-shaped groove 160. A doped region 176 can be optionally formed between the two doped regions 172 and 174 in the silicon substrate 152 by an n⁺ or n⁻ ion implanting process, and the doped region 176 is positioned above the doped region 154 but below the V-shaped groove 160 to guide induced current, as shown in FIG. 13(b). Particularly, the doped region 154 serves as the drain electrode of a transistor, and the doped regions 172 and 174 serve as the source electrode of the transistor.

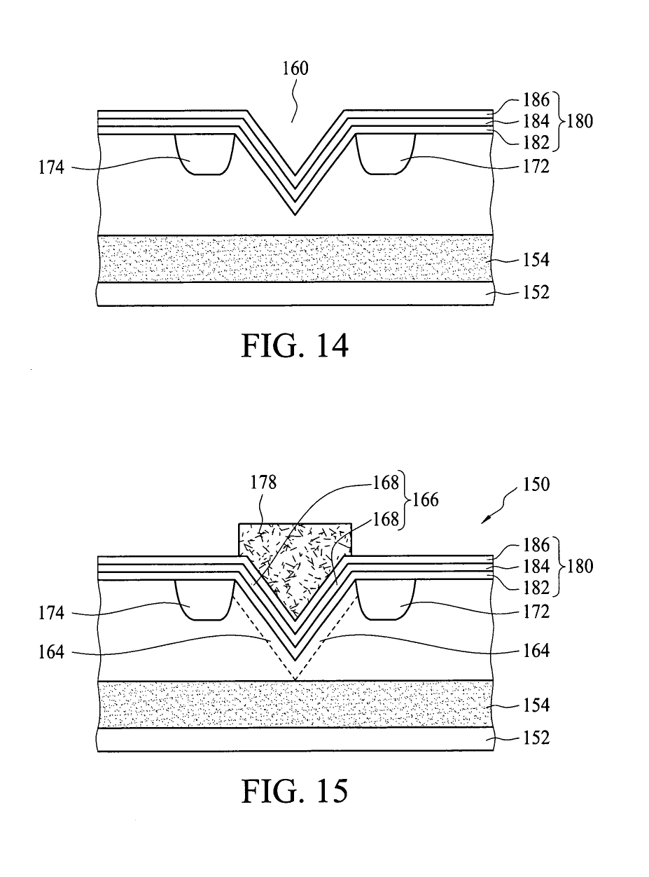

Referring to FIG. 14, deposition processes are performed to form a first oxide layer 182 on the surface of the silicon substrate 152, a silicon nitride layer 184 on the surface of the first oxide layer 182, and a second oxide layer 186 on the surface of the silicon nitride layer 184 so as to form a dielectric stack 180 on the surface of the silicon substrate 152. A conductive layer 178 made of polysilicon is subsequently formed on the surface of the dielectric stack 180 and above the V-shaped groove 160 to complete the flash memory structure 150, as shown in FIG. 15. Particularly, the flash memory structure 150 includes a carrier-trapping region 166 having a plurality of trapping sites 168 disposed in the silicon nitride layer 184 of the dielectric stack 180 on the two inclined surface planes 162 of the V-shaped groove 160.

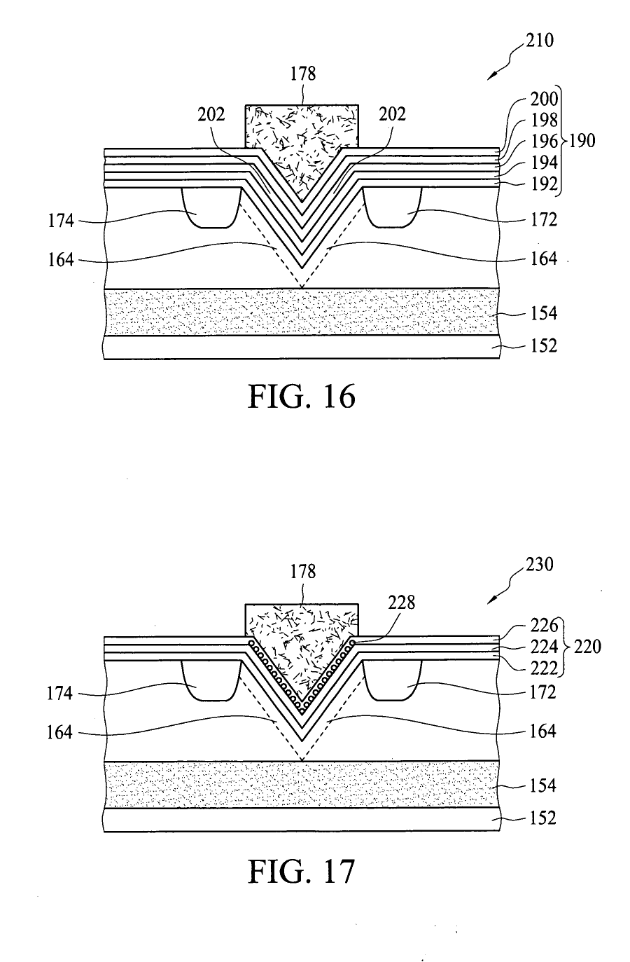

In addition, the application of the present invention is not limited to the SONOS flash memory as describe above. FIG. 16 illustrates a flash memory structure 120 having a dielectric stack 190 according to another embodiment of the present invention. The dielectric stack 190 can be prepared by steps of forming a first oxide layer 192 on the surface of the silicon substrate 152, forming a first silicon nitride layer 194 on the surface of the first oxide layer 192, forming a silicon-containing layer 196 made of polysilicon or silicon germanium on the surface of the first silicon nitride layer 194, forming a second silicon nitride layer 198 on the surface of the silicon-containing layer 196, and forming a second oxide layer 200 on the surface of the second silicon nitride layer 198. Particularly, the trapping sites 202 are positioned in the silicon-containing layer 196.

FIG. 17 illustrates a flash memory structure 130 including a dielectric stack 220 having a plurality of trapping sites disposed therein according to another embodiment of the present invention. The dielectric stack 220 can be prepared by forming an oxide layer 222 on the surface of the silicon substrate 152, forming a silicon nitride layer 224 on the surface of the oxide layer 222, forming a plurality of nanocrystals 228 serving as the trapping sites on the surface of the silicon nitride layer 224, and forming a cover layer 226 made of silicon oxide or silicon nitride covering the nanocrystals 228 and the silicon nitride layer 224. Particularly, the nanocrystals 228 are made of semiconductor material, metal, alloy of metal, or silicide, wherein the metal can be cobalt, nickel or tungsten, and the semiconductor material can be silicon or silicon germanium.

The above-described embodiments of the present invention are intended to be illustrative only. Numerous alternative embodiments may be devised by those skilled in the art without departing from the scope of the following claims.

What is claimed is:

1. A flash memory structure, comprising:
a semiconductor substrate having at least one concave structure positioned on the surface of the semiconductor substrate;
two first doped regions positioned in the semiconductor substrate and at two sides of the concave structure;
at least one carrier-trapping region positioned in the concave structure; and
a conductive layer positioned above the concave structure.

2. The flash memory structure of claim 1, wherein the concave structure comprises two grooves having a U-shaped or V-shaped profile.

3. The flash memory structure of claim 2, wherein the two grooves are separated by a protrusion.

4. The flash memory structure of claim 1, wherein the carrier-trapping region comprises a dielectric stack positioned in the concave structure.

5. The flash memory structure of claim 4, wherein the dielectric stack comprises:
a first oxide layer positioned on the surface of the semiconductor substrate;
a nitride block positioned on the surface of the first oxide layer and in the concave structure; and
a second oxide layer covering the first oxide layer and the nitride block.

6. The flash memory structure of claim 1, wherein the semiconductor substrate is a silicon substrate, and the concave structure has an inclined plane with (111) orientation of the silicon substrate.

7. The flash memory structure of claim 1, wherein the semiconductor substrate is a silicon substrate, and the concave structure has a bottom plane with (100) orientation of the silicon substrate.

8. The flash memory structure of claim 1, wherein the two first doped regions are used as a source electrode and a drain electrode.

9. The flash memory structure of claim 1, wherein the concave structure is a U-shaped or V-shaped groove.

10. The flash memory structure of claim 9, further comprising:
a second doped region positioned in the semiconductor substrate and below the V-shaped groove; and
a dielectric stack positioned at least on the surface of the V-shaped groove, wherein the dielectric stack includes the carrier-trapping region having a plurality of trapping sites.

11. The flash memory structure of claim 10, wherein the dielectric stack comprises:
a first oxide layer positioned on the surface of the semiconductor substrate;
a nitride layer positioned on the surface of the first oxide layer, wherein the trapping sites are positioned in the nitride layer; and
a second oxide layer positioned on the surface of the nitride layer.

12. The flash memory structure of claim 10, wherein the dielectric stack comprises:
a first oxide layer positioned on the surface of the semiconductor substrate;
a first nitride layer positioned on the surface of the first oxide layer; and
a silicon-containing layer positioned on the surface of the first nitride layer, wherein the trapping sites are positioned in the silicon-containing layer made of polysilicon or silicon germanium;
a second nitride layer positioned on the surface of the silicon-containing layer; and
a second oxide layer positioned on the surface of the second nitride layer.

13. The flash memory structure of claim 10, wherein the dielectric stack comprises:
an oxide layer positioned on the surface of the semiconductor substrate;
a nitride layer positioned on the surface of the oxide layer;
a plurality of nanocrystals serving as the trapping sites positioned on the surface of the nitride layer; and
a cover layer made of silicon oxide or silicon nitride covering the nanocrystals and the nitride layer.

14. The flash memory structure of claim 13, wherein the nanocrystals are made of material selected from the group consisting of silicon, silicon germanium, metal, alloy of metal, and silicide.

15. The flash memory structure of claim 10, wherein the semiconductor substrate is a (100)-oriented silicon substrate, and the V-shaped groove has inclined surface planes with (111) orientation.

16. The flash memory structure of claim 10, wherein the second doped region is used as a drain electrode.

17. The flash memory structure of claim 10, wherein the two first doped regions are used as source electrodes.

18. The flash memory structure of claim 10, wherein the conductive layer is used as a gate electrode.

19. The flash memory structure of claim 10, further comprising a third doped region positioned in the semiconductor substrate, between the two first doped regions, and below the V-shaped groove.
